(19) United States
(12) Patent Application Publication
(10) Pub. No.: US 2026/0052665 A1
(43) Pub. Date: Feb. 19, 2026

(54) LOW-POWER ELECTRONIC COMPONENTS WITH UNIPOLAR THIN-FILM TRANSISTORS

(71) Applicants: Shubham RANJAN, Waterloo (CA); Manoj SACHDEV, Waterloo (CA)

(72) Inventors: Shubham RANJAN, Waterloo (CA); Manoj SACHDEV, Waterloo (CA)

(21) Appl. No.: 19/298,005

(22) Filed: Aug. 12, 2025

Related U.S. Application Data
(60) Provisional application No. 63/682,418, filed on Aug. 13, 2024.

(51) Int. Cl. H10B 10/00; G11C 11/412; G11C 11/419; H03K 3/037

(52) U.S. Cl. CPC H10B 10/12; G11C 11/412; G11C 11/419; H03K 3/0372; H10B 10/18

(57) ABSTRACT

Low-power electronic components are disclosed, fabricated using a single type of unipolar thin-film transistor (uTFT), such as n-type or p-type devices. The components include logic structures such as static random-access memory (SRAM), data flip-flops (DFFs), and latches, and are particularly suited for use in flexible or display-integrated electronics. Each logic structure comprises a logic core coupled to external power, ground, and optionally control signal lines via two or more fabrics of uTFT-based switching elements. The arrangement avoids direct-current conduction paths between VDD and VSS, or other external lines such as word lines or bit lines. The result is a class of uTFT logic circuits with reduced static power consumption, even in the absence of complementary transistor types. Applications include system-on-panel designs, flexible displays, wearable sensors, and ultra-low-power IoT devices.

### CROSS-REFERENCE TO RELATED APPLICATION

This application claims priority to U.S. Provisional patent application 63/682,418, filed Aug. 13, 2024. The entire contents of the foregoing are incorporated herein by reference.

### FIELD

The disclosure is generally directed at electronic components and more specifically at low-power electronic components with unipolar thin-film transistors. Examples of electronic components include, but are not limited to, SRAM, DFF or D-Latch.

### BACKGROUND

With fast growing interest in flexible displays, conformable on-body sensors, and Internet-of-Things (IoT) devices, the demand for low-thermal, budget-friendly and flexible electronics has been rising owing to its low-cost and high-volume fabrication capabilities. The realization of such technologies has the potential to enable a wide range of applications in medical, biological, and other consumer electronics. The suitability of amorphous silicon (a-Si:H), transition metal-oxide and organic thin-film transistors (TFTs) has been demonstrated to varying degrees of success.

However, being fundamentally different from crystalline-silicon CMOS technologies, disordered semiconductor TFTs are mostly unipolar, lacking the benefit of having a complementary transistor type. In general, static random-access memories (SRAMs) and data flip-flops (DFFs) using unipolar TFTs are designed in a diode configuration, which results in high static power consumption. One of the ways to counter high static leakage is to fabricate a complementary TFT, but this results in increased fabrication costs. Therefore, it has always been challenging to realize memories and DFFs in a cost-effective manner due to the high static leakage current. Consequently, SRAMs and DFFs are rarely implemented on TFT backplanes.

Therefore, there is provided novel low-power electronic components with unipolar thin-film transistors.

### SUMMARY

The disclosure is directed at novel low-power electronic components using unipolar thin-film transistor (TFT or uTFT, as the context requires). Aspects of the disclosure include low-power electronic components that are directed to logic structures. The TFTs can be positioned within the electronic components to act as logic gates within the components. Examples of logic structures include, but are not limited to, SRAMs, DFFs and/or latches. In some embodiments, the logic structures provide a static leakage current reduction for the electronic components compared to conventional diode-configured equivalents. The logic structures of the disclosure may be used in flexible electronics and TFT based circuits such as displays. One advantage is the ability to store information on the backplane leading to intelligent, reliable and power-efficient TFT backplanes.

Aspects of the disclosure address different problems such as, but not limited to, high static leakage current in unipolar TFT SRAM memory; high static leakage current in unipolar TFT DFFs (D Flip-Flops); high static leakage current in unipolar TFT D-Latch components; limited output swing in DFFs and/or limited output swing in D-Latch components. Embodiments of the disclosure provide advantages over current solutions, these advantages include, but are not limited to, lowering power consumption in TFT SRAM memory; lowering power consumption in TFT DFF (D Flip-Flop); lowering power consumption in TFT Latch; providing a full output swing in DFF and/or providing a full output swing of D-Latch.

Aspects of the disclosure provide a Static Random Access Memory cell with uTFT type, and is responsive to bitline and bitline complement, and wordline, and comprises: a low-leakage latch consisting of two low-leakage inverters where output of the first inverter is coupled to the input of the second inverter; and the output of the second inverter is coupled to the input of the first inverter; and the said each low-leakage inverter with two stages where the drain of the driver transistor of the first stage is coupled to the inverter output, and its source is coupled to the ground, and the gate of the driver transistor is the input of the said low-leakage inverter; and the source of the second transistor is coupled to the output of the said low-leakage inverter, and its drain is connected to the power supply, and its gate is connected to the output of the second stage of the said low-leakage inverter; and the second stage of the said low-leakage inverter consisting of two transistors where the source of the first transistor is coupled to the ground, and its drain is connected to the second stage output, and its gate is coupled to the said low-leakage inverter input, and the second transistor of the second stage where its source is coupled to the second stage output, and its drain is coupled to the supply voltage, and its gate is coupled to the said low-leakage inverter output; and two access transistors where the source terminal of the first access transistor is coupled to the input of the first said low-leakage inverter, and its drain is coupled to the bitline, and its gate is coupled to the wordline; and the source of the second access transistor is coupled to the input of the second said low-leakage inverter, and its drain is coupled to the bitline complement, and its gate is coupled to the wordline.

Aspects of the disclosure provide a low-power electronic circuit fabricated using a single type of unipolar thin-film transistors (uTFTs), the circuit comprising: a first inverter comprising a first pair of uTFTs connected in series between a power supply rail (VDD) and a ground rail (VSS), and having an inverter output node; a second inverter comprising a second pair of uTFTs connected in series between VDD and VSS, and having an output node coupled to the input of the first inverter; one or more access transistors connected to respective bit lines and controlled by a word line or clock line; wherein the source or drain terminals of at least one transistor in each inverter are selectively connected to the output node of the opposite inverter such that, in a static state, all current paths between VDD and VSS are blocked by at least one off-state transistor.

An aspect of the specification provides a logic structure including unipolar thin-film transistors (uTFTs) of the same type for connection to a plurality of external lines including: a logic-core; a first-fabric connected to the logic core including: a first plurality of switching-uTFTs each with an on-state and an off-state; each of the first plurality of switching-uTFT having: a first-fabric external terminal connected to one of the external lines; a first-fabric logic terminal connected to the logic core; and, a first-fabric gate terminal connected to the logic core for selectively activating the on-state or the off-state; and, a second-fabric connected to the logic-core, including: a second plurality of switching-uTFTs each with an on-state and an off-state; each of the second plurality of switching u-TFT having: a second-fabric external terminal connected to another one of the external lines; a second-fabric logic terminal connected to at least one of the first plurality of switching uTFts via the logic core; and, a second fabric gate terminal connected to a node that is distinct from any of the external lines.

An aspect of the specification provides a logic structure wherein the uTFTs are all p-type.

An aspect of the specification provides a logic structure wherein the uTFTs are all n-type.

An aspect of the specification provides the logic structure of clam 1 wherein logic structure is an SRAM and the logic core connects to a plurality of additional external lines including a word line (WL), and at least one bit line (BL), and wherein the node is distinct from any of the additional external lines.

An aspect of the specification provides a logic structure wherein: the first-fabric includes four uTFTs; the second-fabric include four uTFTS; the logic core includes at least two additional uTFTs.

An aspect of the specification provides a logic structure, wherein the logic core includes at least four additional uTFTs including a pair of uTFTs forming an access path to the at least one bit line (BL) and a pair of uTFTs forming a dedicated read port coupled to a read bit line (RBL).

An aspect of the specification provides a logic structure wherein the logic core further includes a second pair of uTFTs forming a complementary read port coupled to a second read bit line (RBLB) to provide differential read capability.

An aspect of the specification provides a logic structure, wherein a first one of the second-fabric logic terminals is a drain connected to a node Qb in the logic core and a second one of the second-fabric logic terminals is a drain connected to a node Q in the logic core.

An aspect of the specification provides a logic structure wherein the plurality of additional external lines includes a second bit line, a read word line and a read bit line.

An aspect of the specification provides a logic structure, wherein the logic core includes a latch formed by first and second inverters connected in a back-to-back configuration, the first inverter corresponding to the first fabric and the second inverter corresponding to the second fabric.

An aspect of the specification provides the logic structure of clam 1 wherein the logic core is a data flip-flop.

An aspect of the specification provides a logic structure wherein the logic core includes a plurality of additional uTFts and capacitors, and wherein a first node is feedback to a gate of a first additional uTFt; and a second node is feedback to a gate of a second additional uTFt;, a third node is feedback to a gate of a third additional uTFt, and an output is feedback to a gate of a fourth additional uTFs.

An aspect of the specification provides a logic structure, wherein the feedback configuration eliminates a short-circuit path between the external lines in a logic “0” output state and a logic “1” output state.

An aspect of the specification provides a logic structure, wherein the logic core employs a bootstrapping technique to achieve full output swing and includes an output feedback from a node in the logic core to a gate terminal of one of the first plurality of switching-uTFTs to form a half-latch configuration that reduces static power consumption by eliminating any direct-current path between VDD and VSS.

An aspect of the specification provides a logic structure, wherein the logic core is implemented in a two-master, one-slave architecture; the logic core being configured such that, during a negative edge of a clock signal, data is loaded into the first master latch, and during a positive edge of the clock signal, data is loaded into the second master latch, the slave latch being configured to selectively receive data from the first master latch during the positive edge and from the second master latch during the negative edge, wherein full output swing is achieved using bootstrapped logic.

An aspect of the specification provides a logic structure wherein a plurality of the data flip-flops are connected in series to form a scan-chain of data flip-flops.

An aspect of the specification provides the logic structure of clam 1 wherein the logic core is a data latch.

An aspect of the specification provides a logic structure, wherein the logic core is a data latch configured to receive an input, a clock signal, and a complementary clock signal, the logic core including a capacitor and being arranged to employ a bootstrap technique to achieve full output swing, with an output feedback from an output node and from an internal node to form a half-latch configuration.

### BRIEF DESCRIPTION OF THE DRAWINGS

Embodiments of the present disclosure are illustrated as an example and are not limited by the figures of the accompanying drawings, in which:

FIG. 1 is a schematic diagram of a conventional 6T SRAM using unipolar TFT;

FIG. 2a is a schematic diagram showing a leakage path for the SRAM of FIG. 1 when data at node Q is logic “1”;

FIG. 2b is a schematic diagram showing a leakage path for the SRAM of FIG. 1 when data at node Q is logic “0”;

FIG. 3 is a schematic diagram of a 10T SRAM cell in accordance with the disclosure using unipolar TFT devices;

FIG. 4 is a schematic diagram of the 10T SRAM cell of FIG. 3;

FIG. 5 is a schematic diagram of a 12T SRAM cell in accordance with the disclosure using unipolar TFT devices;

FIG. 6 is a schematic diagram of a 14T SRAM cell in accordance with the disclosure using unipolar TFT devices;

FIG. 7a is a schematic diagram of another embodiment of a 10T SRAM cell;

FIG. 7b is a schematic diagram of another embodiment of a 12T SRAM cell;

FIG. 7c is a schematic diagram of another embodiment of a 14T SRAM cell;

FIG. 8 is a table showing static power consumption between embodiments of the disclosure vs conventional SRAM cells;

FIG. 9a is a chart showing Read static noise margin (SNM) for a 10T SRAM cell;

FIG. 9b is a chart showing Write SNM for a 10T SRAM cell;

FIG. 10 is a schematic diagram of a conventional DRR using unipolar TFTs;

FIG. 11a is a schematic diagram of a conventional DFF using TFTs when output is logic 0;

FIG. 11b is a schematic diagram of a conventional DFF using TFTs when output is logic 1;

FIG. 12 is a schematic diagram of a low-power DFF using unipolar TFTs in accordance with the disclosure;

FIG. 13a is a schematic diagram of the low-power DFF of FIG. 12 when output is logic “0”;

FIG. 13b is a schematic diagram of the low-power DFF of FIG. 12 when output is logic “1”;

FIG. 14a is a graph showing an input waveform and a clock (CLK) signal;

FIG. 14b is a graph showing output waveforms of a conventional DFF and the DFF of the disclosure;

FIG. 15 is a table comparing a conventional DFF and the DFF of the disclosure;

FIG. 16a is a schematic diagram of another embodiment of a low-power DFF using unipolar TFT devices in accordance with the disclosure;

FIG. 16b is a schematic diagram of a further embodiment of a low-power DFF using unipolar TFT devices in accordance with the disclosure;

FIG. 16c is a schematic diagram of a further embodiment of a low-power DFF using unipolar TFT devices in accordance with the disclosure; FIG. 17 is a schematic diagram of a test bench for scan-chain of 8 DFFs;

FIG. 18 is a table showing a power comparison of scan-chain using conventional DFFs and DFFs of the disclosure;

FIG. 19 is a schematic diagram of a conventional D-Latch using unipolar TFTs;

FIG. 20 is a schematic diagram of a D-Latch using unipolar TFTs in accordance with the disclosure;

FIG. 21a is a graph showing an input signal and a clock signal;

FIG. 21b is a graph showing output waveforms for a conventional D-latch and a D-Latch in according with the disclosure;

FIG. 22 is a table showing a comparative analysis of a conventional D-Latch vs a D-Latch in accordance with the disclosure;

FIG. 23 is a schematic diagram of another embodiment of a low-power D-Latch using unipolar TFT devices in accordance with the disclosure;

FIG. 24 is a schematic diagram of a low-power dynamic DFF using unipolar TFTs in accordance with the disclosure;

FIG. 25 is a schematic diagram of another embodiment of a low-power dynamic DFF using unipolar TFT devices in accordance with the disclosure;

FIG. 26 is a schematic diagram of a low-power dual edge triggered DFF using unipolar TFTs in accordance with the disclosure;

FIG. 27a is a graph showing an input waveform and a clock (CLK) signal;

FIG. 27b is a graph showing output waveforms of a dual edge triggered DFF of the disclosure;

FIG. 28 is a schematic diagram of another embodiment of a low-power dual edge triggered DFF using unipolar TFT devices in accordance with the disclosure; and,

FIG. 29 is a schematic diagram of another embodiment.

### DETAILED DESCRIPTION

The disclosure is directed at a novel electronic components with a single type of unipolar thin-film-transistor (TFT) technology. In other words, the novel electronic components are fabricated using only n-type or p-type TFTs. In some embodiments, the electronic components include, but are not limited to, static random access memory (SRAM), data flip-flops (DFF) or latches. The unipolar TFTs are used for the different electronic components to provide advantages over current equivalents. Advantages of the disclosure include, but are not limited to, lower power consumption by the components and/or full output swings experienced by the components. Further advantages, in some embodiments, include, but are not limited to, the low-power electronic components using only n-type transistors for TFT fabrication and a reduction in high static power consumption by eliminating any direct path current between VDD and VSS in all TFT circuits.

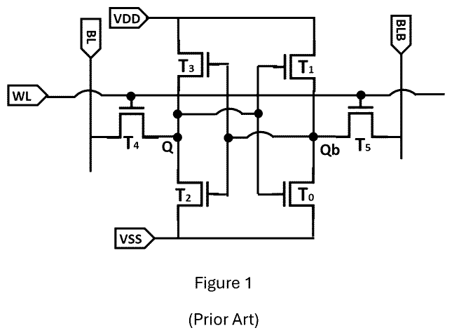

Turning to FIG. 1, a schematic diagram of a conventional 6 transistor or 6T SRAM cell is shown. The SRAM, or SRAM cell includes a set of six (6) transistors (labeled as Tn) where n=0 to 5 connected to a word line (WL), a first bit line (BL), a second bit line (BLB), a negative voltage supply (VSS) and a positive power supply (VDD).

In use, any data stored by the SRAM is retained by a latch formed by a pair of inverters (see FIG. 1), which may be seen as back-to-back inverters. One inverter is formed by transistors T0 and T1 while a second inverter is formed by transistors T2 and T3. The data is stored in complementary form at nodes Q and Qb. In other words, when a “1” is stored at node Q, a “0” is stored at node Qb and vice-versa. In default mode, the WL or WL signal remains at “0”, and the SRAM cell maintains its stored data.

To write new data, the WL is activated. It is assumed that the initial cell or SRAM data is logic “0” at node Q and logic “1” at node Qb. The write operation includes or requires the writing of a logic “0” to node Qb, which as indicated above is assumed to be storing a logic “1”.

To write a logic “0” to node Qb, before WL is activated, BL and BLB are driven to “1” and “0” respectively. During writing, when WL is activated, node Qb is pulled down, and the voltage at node Q starts to rise. As node Qb is pulled below the switching threshold of the second inverter, the data in the SRAM or SRAM cell flips and the new data is written. Writing a logic “0” to or at node Q is performed in a similar manner.

In order to read the stored data, BL and BLB are pre-charged to logic “1” and the WL is activated. If a logic “0” is stored at node Q, then BL starts to discharge through transistors T4 and T2 which is detected by an external periphery circuit. On the other hand, if a logic “0” is stored at node Qb, BLB starts to discharge through transistors T0 and T5.

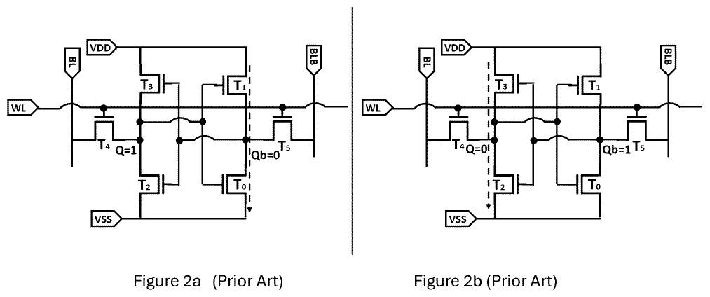

Unfortunately, operation using the SRAM cell of FIG. 1 experiences problems such as, but not limited to, a high static current leakage resulting in higher power consumption. As schematically shown in FIG. 2, there is always a leakage path regardless of the stored data. If the data stored at nodes Q and Qb are logic “1” and logic “0” respectively, then transistors T0 and T1 are on at the same time forming a short circuit between VDD and VSS. On the other hand, if the data stored at nodes Q and Qb are logic “0” and logic “1” respectively, then transistors T2 and T3 are on at the same time forming a short circuit between VDD and VSS. For a conventional 4T SRAM cell, the structure is similar to the 6T SRAM cell shown in FIG. 1, but instead of pull-up transistors T1 and T3, resistors are used.

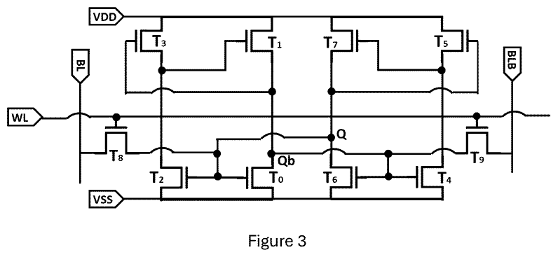

Turning to FIG. 3, a schematic diagram of a low-leakage, or low-power 10T SRAM cell with unipolar TFT in accordance with an embodiment of the disclosure is shown. The 10T SRAM memory cell includes a set of ten (10) transistors (labeled as Tn) where n=0 to 9 connected to a word line (WL), a first bit line (BL), a second bit line (BLB), a negative voltage supply (VSS) and a positive power supply (VDD).

In operation or use, the data in the SRAM cell is retained by a latch formed by back-to-back inverters. A first inverter is formed by transistors T0, T1, T2 and T3 and a second inverter is formed by transistors T4, T5, T6 and T7. The data is stored in complementary form at nodes Q and Qb. In a default mode, WL remain at logic “0”, and the SRAM cell maintains its stored data.

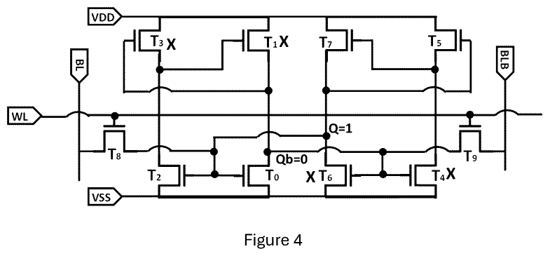

As shown in FIG. 4, when logic “1” is stored at node Q, transistors T1 and T3 of the first inverter are off and transistors T4 and T6 of the second inverter are off. Therefore, any direct current path between VDD and VSS are shut off or stopped, leading to a low or reduction in static power consumption. On the other hand, when logic “0” is stored at node Q, transistors T0 and T2 of the first inverter are off and transistors T5 and T7 of the second inverter are off thereby shutting off or stopping any direct current path between VDD and VSS.

To read the stored data, BL and BLB are pre-charged to logic “1” and WL is activated. If logic “0” is stored at node Q, then BL starts to discharge through transistors T8 and T6 which is sensed by an external periphery circuit such as a sense amplifier in order to be amplified, where needed. On the other hand, if logic “0” is stored at node Qb, BLB starts to discharge through transistors T9 and T0.

To write a new data, to the SRAM cell, WL is activated. Considering the example where the initial cell data is logic “0” at node Q and logic “1” at node Qb, a write operation includes writing a logic “0” to node Qb, which is currently storing a logic “1”. To do so, before WL is activated, BL and BLB are driven to logic “1” and logic “0” respectively. During writing, when WL is activated, node Qb is pulled down, and the voltage at node Q starts to rise. As node Qb is pulled down, below the switching threshold of the first inverter a, the data in the cell flips and new data is written. Writing logic “0” at or to node Q is performed in a similar manner.

As such, the power consumption is lowered and the leakage experienced by the 10T embodiment of the disclosure compared with current solutions is reduced or eliminated due to the design, connections and/or orientation of the set of transistors within the SRAM cell. In one embodiment, this is achieved by eliminating direct current paths between specific transistors. In experiments, it was determined that the 10T SRAM cell of FIG. 3 consumes about 99.98% less leakage power compared to the conventional 6T SRAM cell of FIG. 1.

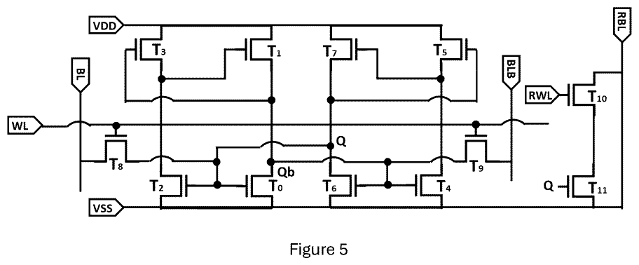

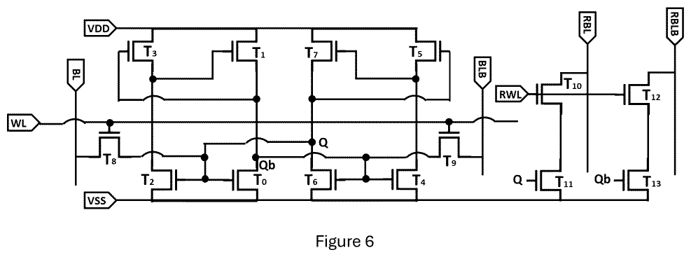

Further embodiments of novel two port SRAM memory or memory cells are shown in FIGS. 5 and 6 which are a schematic diagram of a 12T SRAM memory cell and a schematic diagram of a 14T SRAM memory cell using unipolar TFT, respectively.

Turning to FIG. 5, the SRAM memory cell includes a set of twelve (12) transistors (labeled as Tn) where n=0 to 11 connected to a word line (WL), a first bit line (BL), a second bit line (BLB), a negative voltage supply (VSS), a positive power supply (VDD), a read/write line (RWL) and a read bit line (RBL). The SRAM memory cell of FIG. 5 operates in a similar manner to the embodiment shown in and described with respect to FIG. 3. The extra transistors, seen as transistors T10 and T11, form a dedicated read port terminating at the RBL, while the conventional port with BL and BLB is used for writing into the cell. One advantage of the dedicated read port is faster read operation. Additionally, these two ports can work independently enhancing the memory utilization.

Turning to FIG. 6, the SRAM memory cell includes a set of fourteen (14) transistors (labeled as Tn) where n=0 to 13 connected to a word line (WL), a first bit line (BL), a second bit line (BLB), a negative voltage supply (VSS), a positive power supply (VDD), a read/write line (RWL), a first read bit line (RBL) and a second read bit line (RBLB). The SRAM memory cell of FIG. 6 operates in a similar manner to the embodiment shown in and described with respect to FIG. 5. In comparison with the embodiment of FIG. 5, the inclusion of transistors T12 and T13, provide a differential read port which improves the speed of the read operation, and simplifies the design of a read circuit.

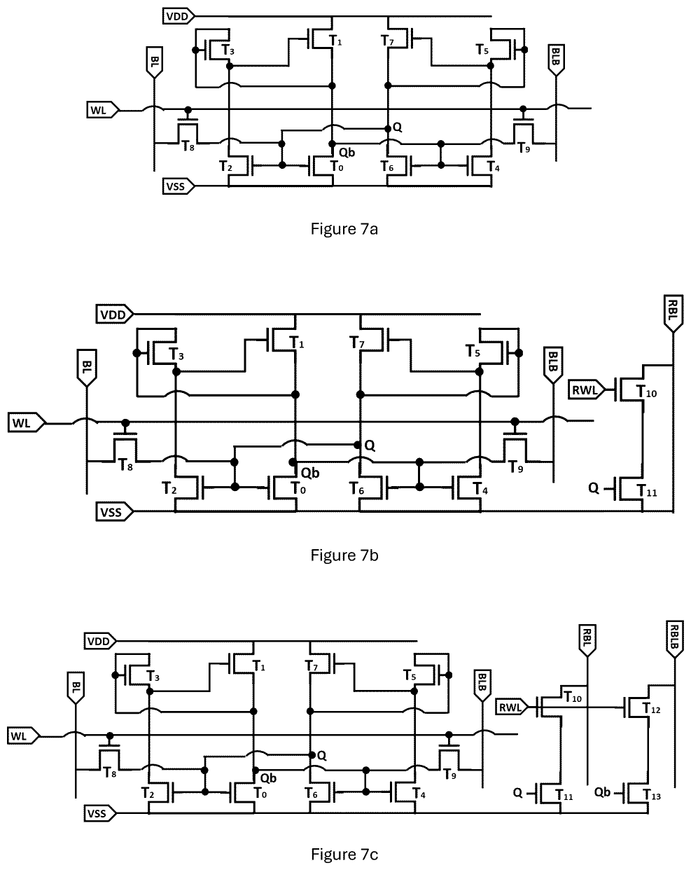

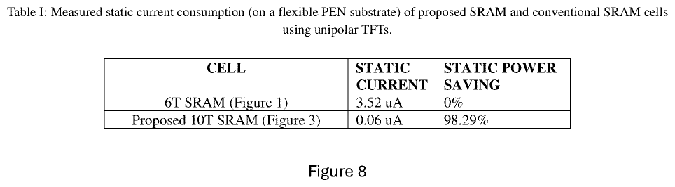

FIGS. 7a to 7c are schematic diagrams of further embodiments of a 10T SRAM memory cell (FIG. 7a), a 12T SRAM memory cell (FIG. 7b) and a 14T SRAM memory cell (FIG. 7c). The difference between the embodiments of FIGS. 7a to 7c compared with the ones described in FIGS. 3, 5 and 6, respectively, is that the drain of transistor T3 is connected to node Qb and the drain of transistor T5 is connected to node Q to further reduce or eliminate any static power consumption. The embodiments of FIGS. 7a to 7c reduces the leakage further by about 10× with respect to the embodiments of FIGS. 3, 5 and 6. FIG. 8 (Table I) is a table showing a leakage comparison for the 10T SRAM cells of the disclosure (FIGS. 3 and 7a) and conventional 4T and 6T SRAM cells.

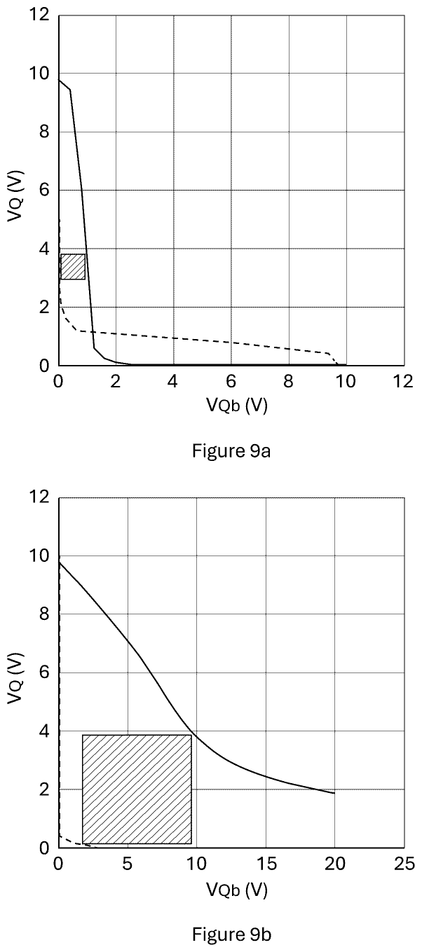

Turning to FIGS. 9a and 9b, graphs showing a Read static noise margin (SNM) for a 10T SRAM cell (FIG. 9a) and a Write SNM margin for a 10T SRAM memory cell (FIG. 9b) are provided for each of the 10T embodiments. As known to an expert in the art, the SNM for an SRAM memory cell is a measure of its stability.

To plot the Read SNM, the access transistors of the SRAM cell are turned on. As shown in FIG. 9a, the Voltage Transfer Characteristic (VTC) and the Inverse VTC (VTC-1) are plotted. VQB (voltage at node Qb) vs VQ (voltage at node Q) is plotted by sweeping VQ for the VTC, and VQ versus VQb by sweeping VQb for the VTC-1. The resulting two-lobed curve is known as a “butterfly curve,” and is used to calculate the Read SNM which is defined as the length of the longest side of the greatest square that can be inserted inside the lobes of the “butterfly curve”. This represents a maximum or a high amount of voltage noise that can be injected at the internal nodes of the two inverters while maintaining stored data in the cell during a read operation.

The write SNM is defined as the maximum or a high amount of noise that can be injected at the internal nodes of the two inverters before the SRAM cell is flipped. To plot Write SNM, BL and BLB are connected to VDD and GROUND, and the access transistors are turned on. The transfer characteristics VTC and VTC-1 are plotted in the similar manner as discussed above with respect to the Read SNM. The Write SNM may be calculated graphically by computing the length of the largest square that can be inserted between the VTC and VTC-1 curves. There are no lobes on the “butterfly curve” during a successful write process. During a write operation, the SRAM cell is monostable which means that the SRAM can have only one data during writing i.e., the one that is being written. The cell will regain bi-stability if the VTC and VTC-1 curves on the plot shift by an amount equal to the Write SNM or, in other words, the SRAM can have either data during writing if the noise is more than write SNM, which may lead to write failure. As shown in FIGS. 9a and 9b, the read SNM and write SNM of the 10T SRAM cell are approximately 0.95V and 7.81V respectively.

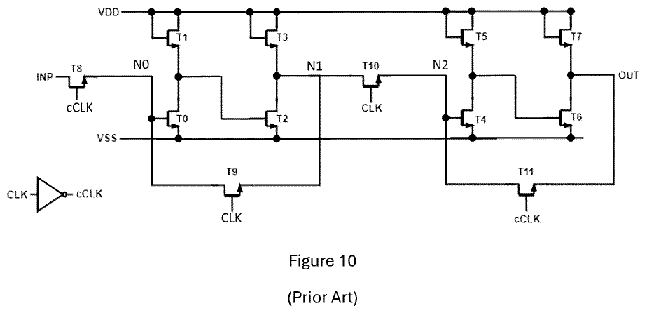

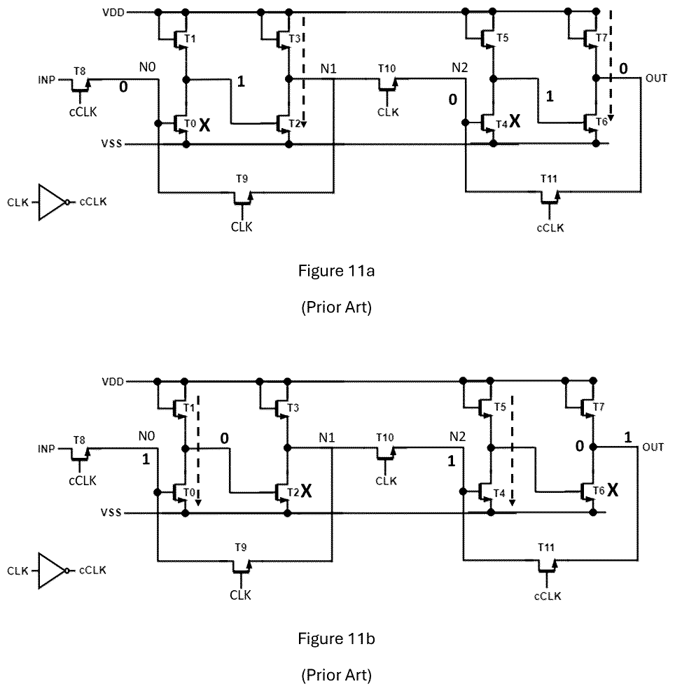

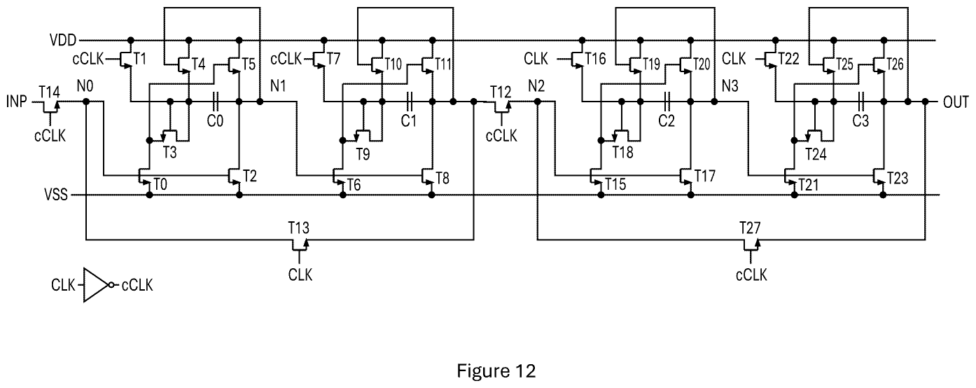

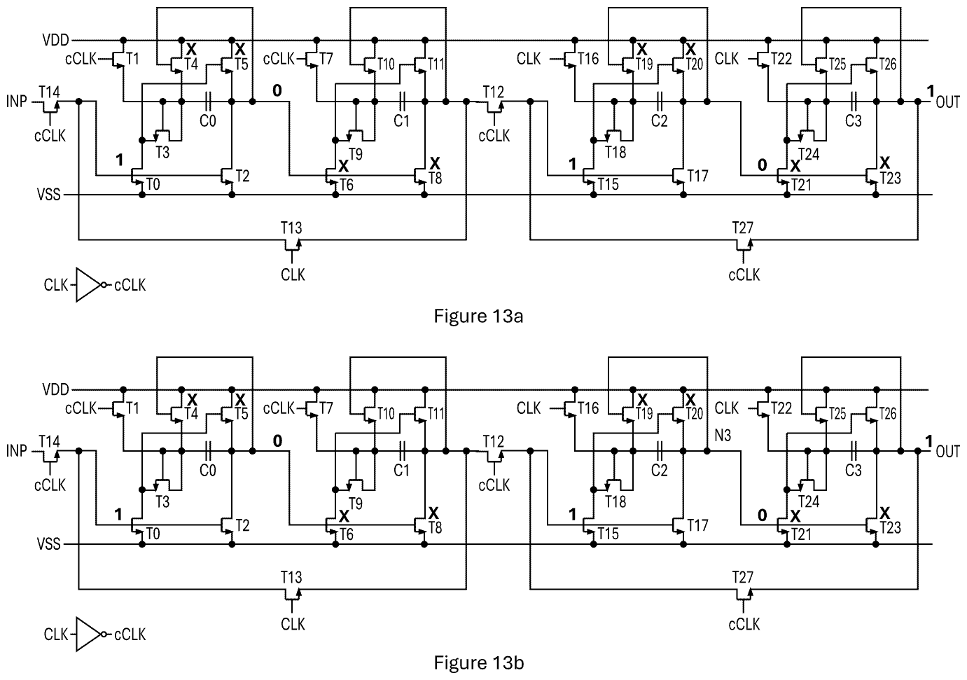

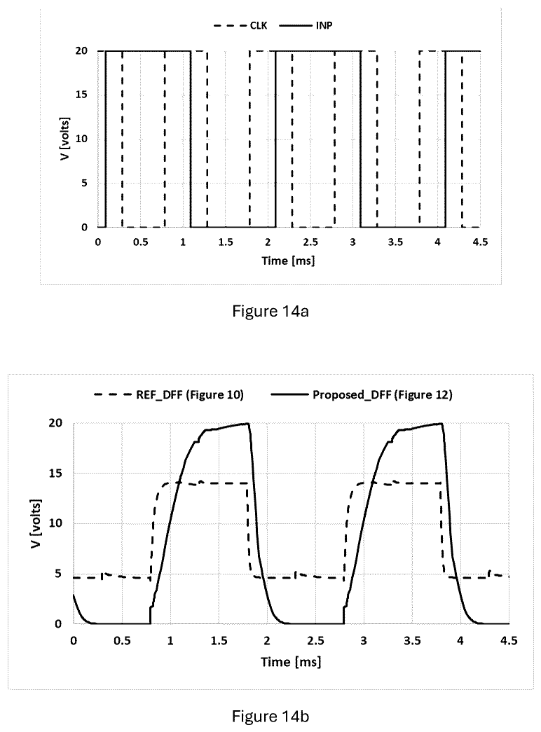

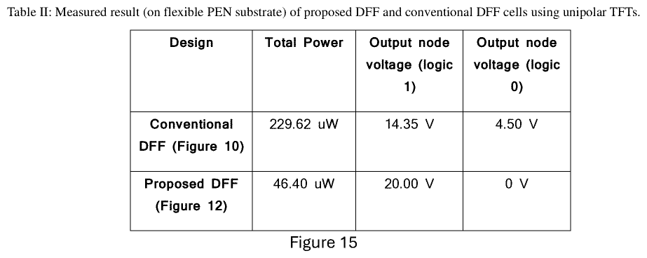

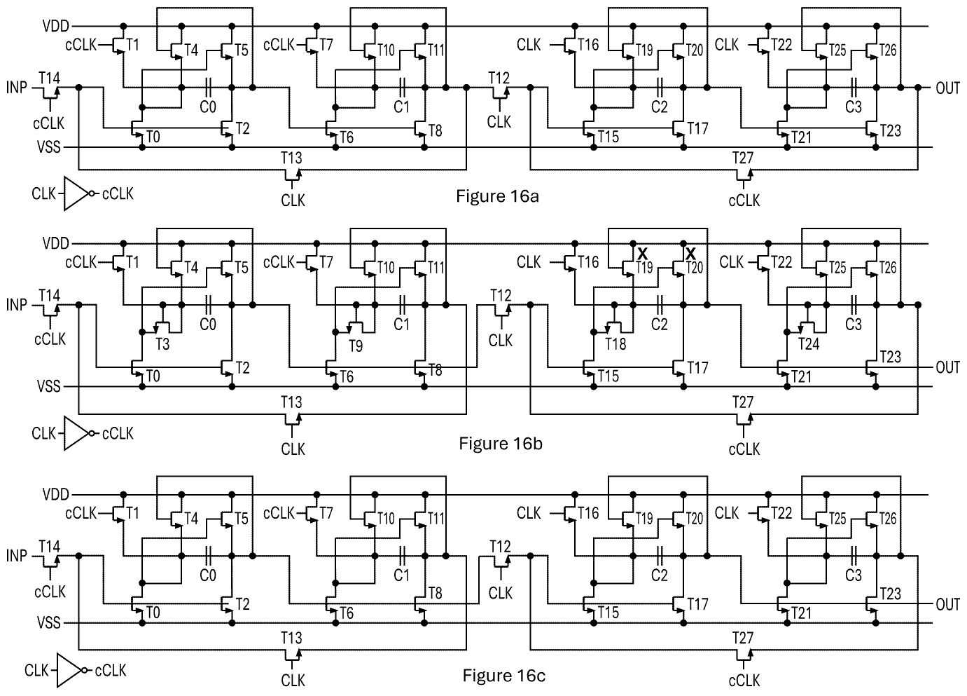

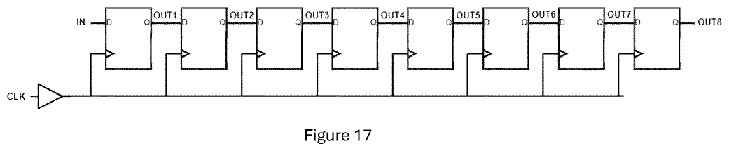

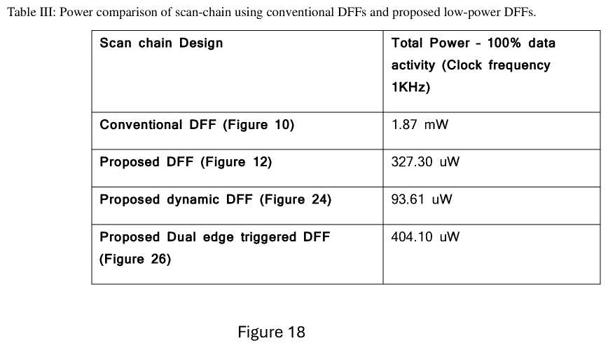

Turning to FIG. 10, a schematic diagram of a conventional D Flip-flop (DFF) component or circuit is shown. The DFF circuit includes a set of transistors that are connected to an input, an output, VSS, a Clock signal and VDD.

In operation, for logic “1” in the internal stages (seen as nodes N1, N2 and N3) and the output, individual diode pull-up transistors are used which are labeled as T1, T3, T5, and T7.

As shown in FIG. 11a, when the output is at logic level “0, transistors T6 and T7 are on thereby not allowing, or preventing, the output from reaching full VSS. Moreover, a short circuit path is formed as transistors T2, T3, T6, and T7 are on at the same time when output is logic “0”, resulting in a high leakage current.

Similarly, as shown in FIG. 11b, because the TFTs being used in the circuit are mostly unipolar, when the output is at logic level “1”, transistor T6 is off and the output reaches VDD-Vt, where Vt is threshold voltage of pull up transistor T7. Moreover, a short circuit path is formed as transistors T0, T1, T4, and T5 are on at the same time when the output is logic “1”, resulting in high leakage current being experienced. Therefore, for this conventional DFF, the DFF has a high static leakage-current and limited output swing.

Turning to FIG. 12, a schematic diagram of a DFF in accordance with the current disclosure is shown. The DFF is directed at an embodiment which is based on a bootstrap technique to achieve full output swing. The DFF includes a set of transistors (where n=0 to 27) that are connected to an input, individual capacitors, an output, a clock signal, VSS and VDD. Within the DFF, there is a feedback that is used to reduce the static leakage. The node N1 is feedback to the gate of T4 transistor which reduces or eliminates the leakage path between VDD and VSS. Similar feedback is arranged from node N0 to the gate of the transistor T10, node N3 to the gate of T19, and node Out to the gate of transistor N25, respectively. The clock signal is used for the enabling transitions in the output and internal node N3 signal, while signal cCLK is used for enabling nodes N1 and N2.

Operation of the DFF is now described with respect to node N1.

### A. Negative Transition of Node N1

When node NO goes high, pull-down transistors or TFTs (T0 and T2) are switched ON, discharging nodes N1 and C. As node C starts to discharge, it starts turning off transistor T5 which, in turn, starts to turn off transistor T4, which speeds up the discharging of node C, and forms a positive feedback loop. As node C is completely discharged, transistor T5 is completely off and node N1 reaches full VSS. As node N1 discharges to full VSS, it turns off transistor T4, eliminating or removing any short circuit path between VDD and VSS thereby reducing static power consumption. Similar functionality is performed with respect to the transistors associated with Nodes N2, N3, and output.

### B. Positive Transition of Node N1

As the node NO goes to logic “0”, pull-down transistors (T0 and T2) are switched OFF. Initially transistors T4 and T5 are off. As the cCLK signal goes high, it charges node B, which, in turn, charges node C. This starts turning on transistor T5 and node N1 starts rising resulting in transistor T4 being turned on and further charging of node B.

This voltage difference between node B and node N1 is held by capacitor CO and provides a boost to node B when the input makes a high-to-low transition.

Since the voltage difference between node B and C is approximately ½ VDD, current from VDD begins to flow through transistor T4 into nodes B and C which gradually turns transistor T5 on. This transient current, Ifb(t), can be expressed by the current-voltage (I-V) relationship of transistor T3 as shown below in Eq. 1. Here, variable “t” represents the time dependence.

$${I}_{fb} ( t ) = \frac{1}{2} {μ}_{n} {C}_{dielec} {\frac{{W}_{4}}{{L}_{4}} [ {V}_{B} ( t ) - {V}_{C} ( t ) - {V}_{T} ]}^{2} \qquad Eq . 1$$

Next, node N1 increases after transistor T5 is turned ON. Assuming transistor T5 operates mostly in saturation mode, its drain-source current I5(t) can be expressed as:

$${I}_{5} ( t ) = \frac{1}{2} {μ}_{n} {C}_{dielec} {\frac{{W}_{5}}{{L}_{5}} [ {V}_{C} ( t ) - {V}_{N 1} ( t ) - {V}_{T} ]}^{2} \qquad Eq . 2$$

As node N1 rises, the voltage at node B is also pushed higher by the capacitor C0. Since the stored voltage difference across the capacitor is approximately ½ VDD from the previous phase, the relationship between VN1(t) and VB(t) is:

$${V}_{B} ( t ) = {V}_{N 1} ( t ) + \frac{1}{2} {V}_{DD} \qquad Eq . 3$$

This bootstrapped feedback loop formed by transistors T5, T3, T4 and capacitor C0 eventually leads to VB which is 3/2 VDD, VC which is approximately 3/2 VDD-VT and VN1=VDD at steady-state.

Therefore, node N1 can reach full output swing and maintain low static leakage current. The operation of nodes N2, N3 and output is same as for N1.

If node N1 transitions to ‘1’, transistors T6 and T8 are switched ON, discharging nodes N2. Transistor T11 starts to turn off, which, in turn, starts to turn off transistor T10. Finally, transistor T11 is completely off and node N2 reaches full VSS. As node N2 discharges to full VSS, it turns off transistor T10, eliminating or removing any short circuit path between VDD and VSS thereby reducing static power consumption. If the node N1 transitions to ‘0’, and as cCLK signal goes high, it charges source terminal of transistor T10, this in-turn charges gate of T11. As the T11 starts to turn on, it turns on transistor T10. These further charges source of T10, and finally drain of T11 reaches full VDD. If the CLK signal is high, data from drain of T11 is transferred to node N2.

If node N2 transitions to ‘1’, transistors T15 and T17 are switched ON, discharging nodes N3. Transistor T20 starts to turn off, which, in turn, starts to turn off transistor T19. Finally, transistor T20 is completely off and node N3 reaches full VSS. As node N3 discharges to full VSS, it turns off transistor T16, eliminating or removing any short circuit path between VDD and VSS thereby reducing static power consumption. If the node N2 transitions to ‘0’, and as CLK signal goes high, it charges source terminal of transistor T19, this in-turn charges gate of T20. As the T20 starts to turn on, it turns on transistor T19. These further charges source of T19, and finally N3 reaches the full VDD.

If node N3 transitions to ‘1’, transistors T21 and T23 are switched ON, discharging output node. Transistor T26 starts to turn off, which, in turn, starts to turn off transistor T25. Finally, transistor T26 is completely off and output node reaches full VSS. As output node discharges to full VSS, it turns off transistor T25, eliminating or removing any short circuit path between VDD and VSS thereby reducing static power consumption. If the node N3 transitions to ‘0’, and as CLK signal goes high, it charges source terminal of transistor T25, this in-turn charges gate of T26. As the T26 starts to turn on, it turns on transistor T25. These further charges source of T25, and finally N3 reaches the full VDD.

As shown in FIG. 13, for both cases when the output is maintained at logic “0” (FIG. 13a) or logic “1” (FIG. 13b), there is no short circuit path between VDD and VSS, thereby reducing the power consumption of the DFF circuit of FIG. 12. The input and clock signals for DFF circuits are shown in FIG. 14a and output waveforms for the DFF circuit of FIG. 12 and the conventional DFF of FIG. 10 are shown in FIG. 14b. FIG. 15 (Table II) is a table comparing operational characteristics between the DFF cell or circuit of FIG. 12 and the conventional DFF cell of FIG. 10.

As shown in FIGS. 16a, 16b, and 16c further embodiments of a DFF circuit in accordance with the disclosure is shown. In the embodiment of FIG. 16a, the DFF circuit is similar to the embodiment of FIG. 12 with some small variations. Specifically, transistors T3, T9, T18, and T24 have been removed in this configuration.

As shown in FIGS. 16b, further embodiment of a DFF circuit in accordance with the disclosure is shown. In the embodiment of FIG. 16b, the DFF circuit is similar to the embodiment of FIG. 12 with some small variations. One variation is that the source of transistors T12 has been connected to drain of T2, instead of drain of T8. The second variation is that the output is connected to drain of T17, instead of drain of T23.

As shown in FIGS. 16c, further embodiment of a DFF circuit in accordance with the disclosure is shown. In the embodiment of FIG. 16c, the DFF circuit is similar to the embodiment of FIG. 16b with some small variations. Specifically, transistors T3, T9, T18, and T24 have been removed in this configuration.

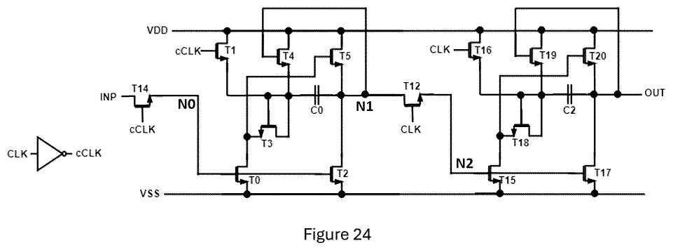

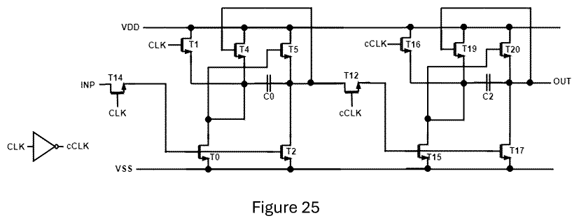

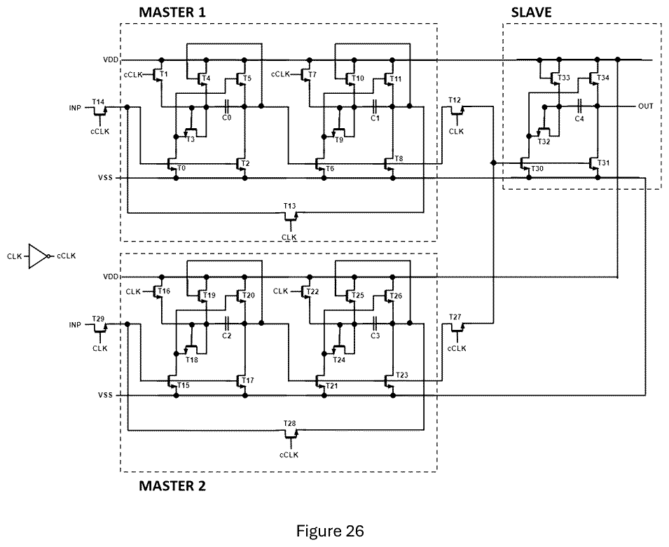

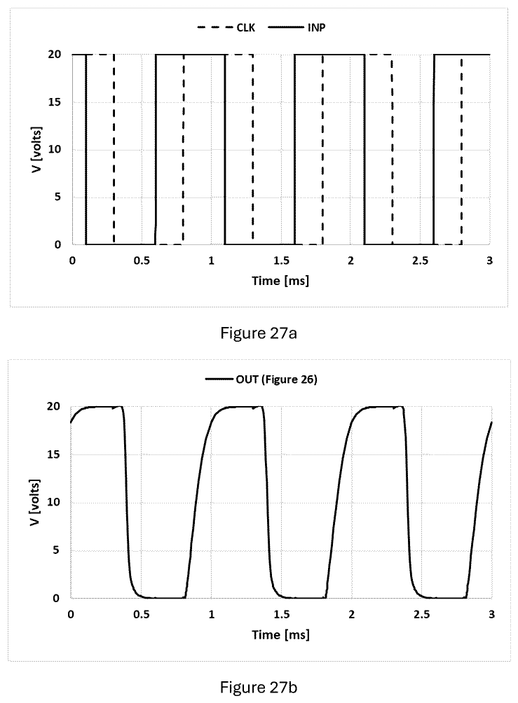

FIG. 17 is a schematic diagram of a scan-chain of eight (8) DFFs connected in series which may be implemented using the DFFs of either FIG. 12, FIG. 16a, FIG. 16b, or FIG. 16c, or conventional DFFs. (The schematic in FIG. 17 is likewise applicable to the variants in FIG. 24, FIG. 25, or FIG. 26, discussed in greater detail below.)

FIG. 18 (Table III) is a comparison of total power used or power consumption for the scan-chain of FIG. 17 between conventional DFFs and the low-power DFFs of the disclosure.

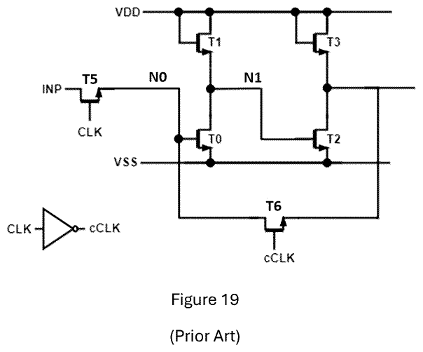

Turning to FIG. 19, a schematic diagram of a conventional D-latch component or circuit is shown. The D-latch includes a set of six transistors (Tn where n=0 to 5) which are connected to an input, VDD and V22. Transistor T5 receives a clock signal which transistor T6 receives a complementary clock signal.

In operation, for a logic “1” in the internal stages node N1 and output, diode pull-up transistors are used (T1 and T3, respectively). When the output is logic “0”, both transistors T2 and T3 are on thereby not allowing the output to reach full VSS. Moreover, a short circuit path is formed as transistors T2 and T3 are on at the same time the output is logic “0”, resulting in a high leakage current.

Similarly, because TFTs are mostly unipolar, when the output is logic “1”, transistor T2 is off and the output reaches VDD-Vt, where Vt is threshold voltage of pull up transistor T3. Moreover, a short circuit path is formed as transistors T0 and T1 are on at the same time when the output is logic “1”, resulting in a high leakage current. Therefore, conventional D-latch components experience high static leakage-current and limited output swing.

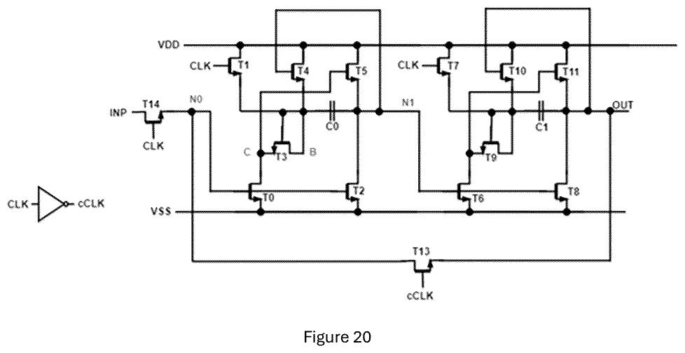

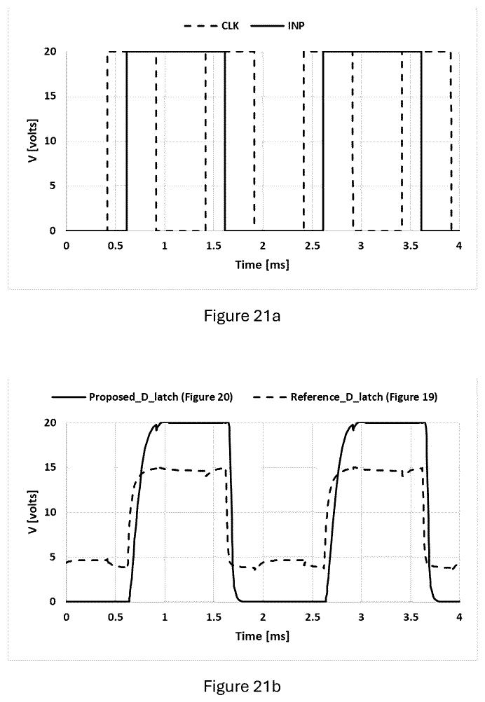

Turning to FIG. 20, a schematic diagram of a low-power D-latch component in accordance with the disclosure is shown. The D-latch component includes a set of transistors which are connected to an input INP, capacitor CO, VDD, VSS and an output OUT. A clock signal CLK and a complementary clock signal 2014 are connected to the inputs of different transistors for enabling transitions in output and internal nodes signal.

The circuit of FIG. 20 is based on a bootstrap technique to achieve full output swing in the D-latch. An output feedback is used at the output OUT and internal node N1 to form a half latch circuit, which reduces static power consumption by eliminating the short between VDD and VSS which is experienced by some current solutions.

One embodiment of operation of the D-latch of FIG. 20 is now described with respect to node N1:

### A. Negative Transition of Node N0

When node NO goes high, pull-down transistors (T0 and T2) are switched on, discharging nodes N0 and C. As node C starts to discharge, it starts turning off transistor T5 which, in turn, starts to turn off transistor T4, which speeds up the discharging of node C and forms a positive feedback loop. Once node C is completely discharged, transistor T5 is completely off and node NO reaches full VSS. As N0 discharges to full VSS, it turns off transistor T4 eliminating any short circuit path between VDD and VSS.

### B. Positive Transition of Node N0

As the node NO goes to logic “0”, pull-down transistors (T0 and T2) are switched OFF. Initially transistors T4 and T5 are off. As the clock signal goes high, it charges node B, which, in turn, charges node C which starts turning on transistor T5 and node N0 starts rising. This results in transistor T4 turning on and a further charging of node B.

This voltage difference between node B and node N0 is held by capacitor C0 and provides a boost to node B when the input INP makes a high-to-low transition.

Since the voltage difference between node B and C is approximately ½ VDD, current from VDD begins to flow through T4 into node B and C which gradually turns on. This transient current, I_{fb}(t), can be expressed by the current-voltage (I-V) relationship of T3 shown in Eq. 4. Here, variable “t” represents the time dependence.

$${I}_{fb} ( t ) = \frac{1}{2} {μ}_{n} {C}_{dielec} {\frac{{W}_{4}}{{L}_{4}} [ {V}_{B} ( t ) - {V}_{C} ( t ) - {V}_{T} ]}^{2} \qquad Eq . 4$$

Next, node NO increases after transistor T5 is turned on. Assuming transistor T5 operates mostly in saturation mode, its drain-source current I5(t) can be expressed as:

$${I}_{5} ( t ) = \frac{1}{2} {μ}_{n} {C}_{dielec} {\frac{{W}_{5}}{{L}_{5}} [ {V}_{C} ( t ) - {V}_{N 1} ( t ) - {V}_{T} ]}^{2} \qquad Eq . 5$$

As N0 rises, the voltage at node B is also pushed higher by the capacitor C0. Since the stored voltage difference across the capacitor is −½ VDD from the previous phase, the relationship between VN0(t) and VB(t) is:

$${V}_{B} ( t ) = {V}_{N 0} ( t ) + \frac{1}{2} {V}_{DD} \qquad Eq . 6$$

This bootstrapped feedback loop formed by transistors T5, T3, T4 and capacitor C0 eventually leads to VB to equal approximate 3/2 VDD, VC to equal approximately 3/2VDD−VT, and VN0=VDD at steady-state. Therefore, node NO can reach full output swing and maintain low static leakage current. The operation of output is same as for N1.

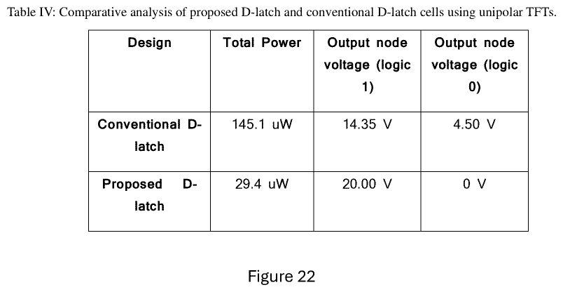

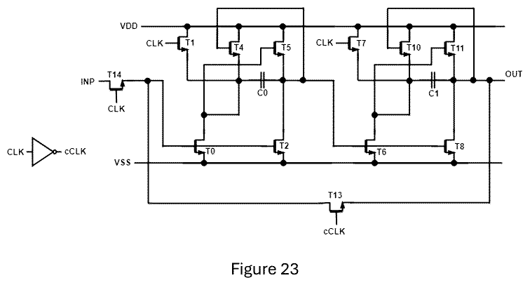

As shown in FIG. 20, for both cases when the output OUT is maintained at logic “0” or logic “1”, there is no short circuit path between VDD and VSS, thereby reducing the power consumption of the D-latch component. The input and clock signals for a D-latch component are shown in FIG. 21a and output waveforms for the D-latch component of FIG. 20 and the conventional D-latch component of FIG. 19 are shown in FIG. 21b. FIG. 22 (Table IV) is a table comparing operational characteristics between the D-latch of FIG. 20 and the conventional D-latch of FIG. 19.

Turning to FIG. 23, other embodiment of D-latch components in accordance with the disclosure are shown. In the embodiment of FIG. 23, the D-latch component is similar to the embodiment of FIG. 20 with some small variations. Specifically, transistors T3 and T9 have been removed in this configuration. In different embodiments, the disclosure may provide a 10T TFT SRAM to reduce static power consumption in SRAM memories; a 12T TFT SRAM to reduce static power consumption in SRAM memories; a 14T TFT SRAM to reduce static power consumption in SRAM memories; a low-power DFF to reduce power consumption and achieve full output swing and/or a low-power D-Latch to reduce power consumption and achieve full output swing.

In some embodiments, the low-power electronic components may be implemented in test chips that include glass and/or flexible substrates. These substrates may include, but are not limited to, flexible electronics; portable displays; low-power displays; AMOLED displays; OLEDOS displays and/or flexible displays.

Variations are contemplated. For example, turning to FIG. 24, a schematic diagram is shown of a low-power dynamic D flip-flop (DFF) in accordance with the present disclosure. FIG. 24 illustrates a variant of the DFF architectures previously shown in FIGS. 16a, 16b, and 16c. The circuit in FIG. 24 employs a bootstrapping technique to achieve full output swing, and incorporates additional output feedback at node N1 to form a half-latch configuration. This feedback path serves to reduce static power consumption by eliminating any direct-current path between VDD and VSS. Clock signals (CLK and cCLK) are used to control transitions at both the output and the internal node N1.

Turning to FIGS. 25, another embodiment of low-power dynamic DFF component in accordance with the disclosure is shown. In the embodiment of FIG. 25, the DFF circuit is similar to the embodiment of FIG. 24 with some small variations. Specifically, transistors T3, and T18 have been removed in this configuration.

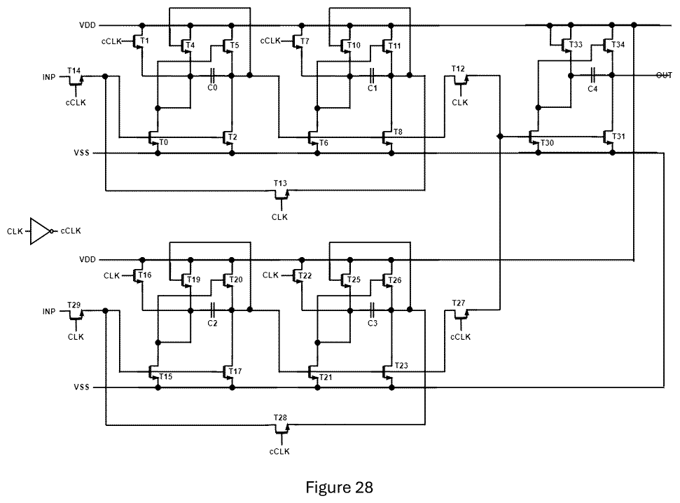

Turning to FIG. 26, a schematic diagram is shown of a low-power, dual-edge-triggered D flip-flop (DFF) in accordance with the present disclosure. The illustrated circuit comprises a two-master, one-slave architecture. During the negative edge of the clock (CLK), data is loaded into the first master latch (MASTER 1). During the positive edge of the clock, data is instead loaded into the second master latch (MASTER 2). The slave latch selectively receives data from MASTER 1 during the positive edge and from MASTER 2 during the negative edge. As a result, the DFF provides dual-edge triggering behavior. Full output swing is achieved using bootstrapped logic, and direct path current is reduced in the master latches through the use of internal node feedback, thereby minimizing static power consumption. Input, clock, and output signal timing for the circuit of FIG. 26 is shown in FIG. 27.

Turning to FIGS. 28, another embodiment of low-power dual edge triggered DFF component in accordance with the disclosure is shown. In the embodiment of FIG. 28, the DFF circuit is similar to the embodiment of FIG. 26 with some small variations. Specifically, transistors T3, T9, T18 and T24 have been removed in this configuration.

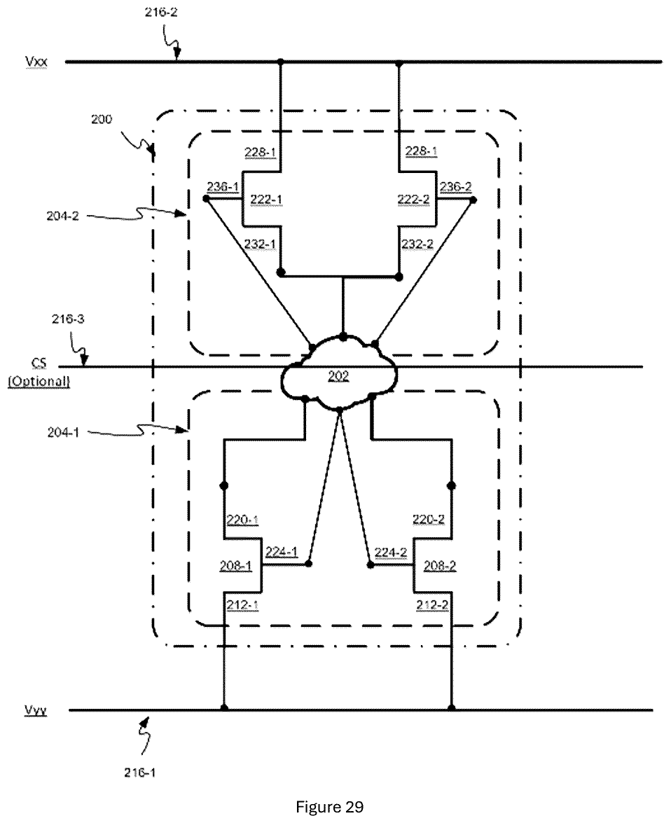

Referring now to FIG. 29, a schematic diagram is shown of a logic structure (200) formed using unipolar thin-film transistors (uTFTs). The logic structure (200) is designed for connection to a plurality of external lines (216), which may include, for example, a power rail Vxx (216-2) and a ground rail Vyy (216-1). FIG. 29 is agnostic as to whether n-type or p-type uTFTs are used, provided the same type is used consistently. Accordingly, in some variants, Vxx (216-2) may serve as the ground rail while Vyy (216-1) may serve as the power rail.

As described further below, the specific function of the logic structure (200) depends on the nature of the logic core (202). For example, an optional control signal line CS (216-3) may be provided as a further external line. Additional external lines similar to CS (216-3) may be present in some embodiments-for example, where the logic core (202) implements an SRAM memory array. In such embodiments, a plurality of CS-type lines 216-3 may be included, such as one or more word lines and bit lines. The CS-type lines 216-3 may thus be input and/or output, including but not limited to read word lines and read bit lines.

The logic structure (200) includes a logic core (202), a first fabric (204-1), and a second fabric (204-2), each of which comprises a respective plurality of switching uTFTs (208, 222) arranged to control conduction paths between the logic core (202) and the external lines (216). In the illustrated embodiment, the first fabric (204-1) is located below the logic core (202), and the second fabric (204-2) is located above it, though other spatial arrangements may also be used and indeed the placement in FIG. 29 is for illustrative purposes.

The first fabric (204-1) includes a first plurality of switching uTFTs (208), each with an on-state and an off-state. Each of these uTFTs (208), includes:
a first-fabric external terminal (212) connected to one of the external lines (216), such as Vyy (216-1);
a first-fabric logic terminal (220) connected to the logic core (202); and
a first-fabric gate terminal (224), also connected to the logic core (202), and configured to selectively activate the respective uTFTs (208) into the on-state or the off-state.

The second fabric (204-2) includes a second plurality of switching uTFTs (222), each also with an on-state and an off-state. Each of these transistors includes:
a second-fabric external terminal (228) connected to another one of the external lines (216), such as Vxx (216-2);
a second-fabric logic terminal (232) connected to at least one of the first plurality of switching uTFTs (208), through the logic core (202); and
a second-fabric gate terminal (236) connected to a node that is distinct from any of the external lines (216).

In the illustrated embodiment, external line CS 216-3 supplies an optional control signal CS. This line may be omitted in some configurations, such as when the logic core (202) implements a flip-flop (e.g. FIGS. 12-13b) or latch structure (FIGS. 21-21). Other implementations, such as when the logic core (202) is used within a memory array such as an SRAM (e.g. FIGS. 5-7c), multiple instances of external line 216-3 may be present, including, for example, word lines and/or bit lines that couple to additional access transistors. In such configurations, the logic structure (200) enables selective and low-leakage access to and from the logic core (202), with isolation from Vxx and Vyy when inactive.

In general, the arrangement shown in FIG. 29 supports embodiments in which the logic core (202) performs a storage or logic function with reduced static power consumption, and thus the present invention can apply to logic circuits beyond the specific example SRAM, DFF and D-latches discussed herein. By using only unipolar uTFTs and controlling which devices are active at any given time, embodiments based on this structure in FIG. 19 can avoid direct-current paths between power and ground in static conditions, achieving significant reductions in leakage power consumption compared to conventional diode-based or always-on unipolar TFT logic.

Table V, below, shows a mapping of the logic structure (200), shown in FIG. 29, to example embodiments of SRAM, DFF and D-latch using unipolar thin-film transistors (uTFTs). For instance, to form embodiment shown in FIG. 3, two instances of logic structure (200) is used. The first fabric (204-1) of first instance is formed by T0 and T2, shown in FIG. 3. While the first fabric second instance of is formed by T4 and T6. Similarly, the second fabric of first instance is formed by T1 and T3, while second fabric (204-2) of second instance is formed by T5 and T7. The logic core component (202) of first instance is T8, and external lines or control signal (CS) of first instance is formed by BL and WL. Similarly, logic core component of second instance is T9, and external lines or control signal (CS) of second instance is composed of BLB and WL. Similarly, other embodiments of SRAMs shown in FIG. 5, FIG. 6, FIG. 7a, FIG. 7b, FIG. 7c are composed of two instances of logic structure (200), shown in FIG. 29. Similarly, to form DFF embodiments shown in FIG. 12, FIG. 16a, FIG. 16b, FIG. 16c, FIG. 26, and FIG. 28, four instances of logic structure (200), shown in FIG. 29, is used. To form DFF embodiments shown in FIG. 24 and FIG. 25, two instances of logic structure (200) is used. To form D-latch embodiments shown in FIG. 20 and FIG. 23, two instances of logic structure (200) is used.

TABLE V
Mapping of FIG. 29 on proposed SRAM, DFF and D-latch cells using unipolar TFTs.

| | | Total | | | | |
|---|---|---|---|---|---|---|
| | | instances | | Second fabric | Logic Core | I/O from |
| | | of logic | First fabric uTFTs | uTFTs | components | Logic Core; |
| | Circuit | structure | (204-1); | (204-2); | (202); | Instance # |
| Embodiment | Type | (200) | Instance # | Instance # | Instance # | (CS lines) |
| FIG. 3 | SRAM | 2 | #1 (T0, T2) | #1 (T1, T3) | #1 (T8) | #1 (BL, WL) |
| | | | #2 (T4, T6) | #2 (T5, T7) | #2 (T9) | #2 (BLB, |
| | | | | | | WL) |
| FIG. 5 | SRAM | 2 | #1 (T0, T2) | #1 (T1, T3) | #1 (T8) | #1 (BL, WL) |
| | | | #2 (T4, T6) | #2 (T5, T7) | #2 (T9, T10, T11) | #2 (BLB, WL, |
| | | | | | | RBL, RWL) |
| FIG. 6 | SRAM | 2 | #1 (T0, T2) | #1 (T1, T3) | #1 (T8, T12, T13) | #1 (BL, WL, |
| | | | | | | RBLB, RWL) |
| | | | #2 (T4, T6) | #2 (T5, T7) | #2 (T9, T10, T11) | #2 (BLB, WL, |
| | | | | | | RBL, RWL) |
| FIG. 7a | SRAM | 2 | #1 (T0, T2) | #1 (T1, T3) | #1 (T8) | #1 (BL, WL) |
| | | | #2 (T4, T6) | #2 (T5, T7) | #2 (T9) | #2 (BLB, |
| | | | | | | WL) |
| FIG. 7b | SRAM | 2 | #1 (T0, T2) | #1 (T1, T3) | #1 (T8) | #1 (BL, WL) |
| | | | #2 (T4, T6) | #2 (T5, T7) | #2 (T9, T10, T11) | #2 (BLB, WL, |
| | | | | | | RBL, RWL) |
| FIG. 7c | SRAM | 2 | #1 (T0, T2) | #1 (T1, T3) | #1 (T8, T12, T13) | #1 (BL, WL, |
| | | | | | | RBLB, RWL) |
| | | | #2 (T4, T6) | #2 (T5, T7) | #2 (T9, T10, T11) | #2 (BLB, WL, |
| | | | | | | RBL, RWL) |
| FIG. 12 | DFF | 4 | #1 (T0, T2) | #1 (T4, T5) | #1 (T1, T3, C0, | #1 (CLK, |
| | | | | | T13, T14) | cCLK, INP) |
| | | | #2 (T6, T8) | #2 (T10, T11) | #2 (T7, T9, C1) | #2 (cCLK) |
| | | | #3 (T15, T17) | #3 (T19, T20) | #3 (T16, T18, C2, | #3 (cCLK, |
| | | | | | T12, T27) | CLK) |
| | | | #4 (T21, T23) | #4 (T25, T26) | #4 (T22, T24, | #4 (CLK) |
| | | | | | C3) | |
| FIG. 16a | DFF | 4 | #1 (T0, T2) | #1 (T4, T5) | #1 (T1, C0, T13, | #1 (CLK, |
| | | | | | T14) | cCLK, INP) |
| | | | #2 (T6, T8) | #2 (T10, T11) | #2 (T7, C1) | #2 (cCLK) |
| | | | #3 (T15, T17) | #3 (T19, T20) | #3 (T16, C2, T12, | Instance #3 |
| | | | | | T27) | (cCLK, CLK) |
| | | | #4 (T21, T23) | #4 (T25, T26) | #4 (T22, C3) | #4 (CLK) |
| FIG. 16b | DFF | 4 | #1 (T0, T2) | #1 (T4, T5) | #1 (T1, T3, C0, | #1 (CLK, |
| | | | | | T13, T14) | cCLK, INP) |
| | | | #2 (T6, T8) | #2 (T10, T11) | #2 (T7, T9, C1) | #2 (cCLK) |
| | | | #3 (T15, T17) | #3 (T19, T20) | #3 (T16, T18, C2, | #3 (cCLK, |
| | | | | | T12, T27) | CLK) |
| | | | #4 (T21, T23) | #4 (T25, T26) | #4 (T22, T24, | #4 (CLK) |
| | | | | | C3) | |
| FIG. 16c | DFF | 4 | #1 (T0, T2) | #1 (T4, T5) | #1 (T1, C0, T13, | #1 (CLK, |
| | | | | | T14) | cCLK, INP) |
| | | | #2 (T6, T8) | #2 (T10, T11) | #2 (T7, C1) | #2 (cCLK) |
| | | | #3 (T15, T17) | #3 (T19, T20) | #3 (T16, C2, T12, | #3 (cCLK, |
| | | | | | T27) | CLK) |
| | | | #4 (T21, T23) | #4 (T25, T26) | #4 (T22, C3) | #4 (CLK) |
| FIG. 20 | D-latch | 2 | #1 (T0, T2) | #1 (T4, T5) | #1 (T1, T3, C0, | #1 (CLK, |
| | | | | | T13, T14) | cCLK, INP) |
| | | | #2 (T6, T8) | #2 (T10, T11) | #2 (T7, T9, C1) | #2 (CLK) |
| FIG. 23 | D-latch | 2 | #1 (T0, T2) | #1 (T4, T5) | #1 (T1, C0, T13, | #1 (CLK, |
| | | | | | T14) | cCLK, INP) |
| | | | #2 (T6, T8) | #2 (T10, T11) | #2 (T7, C1) | #2 (CLK) |
| FIG. 24 | DFF | 2 | #1 (T0, T2) | #1 (T4, T5) | #1 (T1, T3, C0, | #1 (cCLK, |
| | | | | | T14) | INP) |
| | | | #2 (T15, T17) | #2 (T19, T20) | #2 (T16, T18, C2, | #2 (CLK) |
| | | | | | T12) | |
| FIG. 25 | DFF | 2 | #1 (T0, T2) | #1 (T4, T5) | #1 (T1, C0, T14) | #1 (cCLK, |
| | | | | | | INP) |
| | | | #2 (T15, T17) | #2 (T19, T20) | #2 (T16, C2, | #2 (CLK) |
| | | | | | T12) | |
| FIG. 26 | DFF | 4 | #1 (T0, T2) | #1 (T4, T5) | #1 (T1, T3, C0, | #1 (CLK, |
| | | | | | T13, T14) | cCLK, INP) |
| | | | #2 (T6, T8) | #2 (T10, T11) | #2 (T7, T9, C1) | #2 (cCLK) |
| | | | #3 (T15, T17) | #3 (T19, T20) | #3 (T16, T18, C2, | #3 (cCLK, |
| | | | | | T29, T28) | CLK, INP) |
| | | | #4 (T21, T23) | #4 (T25, T26) | #4 (T22, T24, C3, | #4 (CLK, |
| | | | | | T12, T27, T30, | cCLK) |
| | | | | | T31, T32, T33, | |
| | | | | | T34, C4) | |
| FIG. 28 | DFF | 4 | #1 (T0, T2) | #1 (T4, T5) | #1 (T1, C0, T13, | #1 (CLK, |
| | | | | | T14) | cCLK, INP) |
| | | | #2 (T6, T8) | #2 (T10, T11) | #2 (T7, C1) | #2 (cCLK) |
| | | | #3 (T15, T17) | #3 (T19, T20) | #3 (T16, C2, T29, | #3 (cCLK, |
| | | | | | T28) | CLK, INP) |
| | | | #4 (T21, T23) | #4 (T25, T26) | #4 (T22, C3, T12, | #4 (CLK, |
| | | | | | T27, T30, T31, | cCLK) |
| | | | | | T33, T34, C4) | |

As used in Table V, the term “instance #” refers to a particular occurrence of the logic structure (200) of FIG. 29 as implemented within a given circuit embodiment. Each instance represents a self-contained arrangement of a first fabric, a second fabric, and a logic core, together with the external line connections associated with that logic core. In the embodiments described herein, multiple instances of the logic structure (200) may be combined to form a complete functional block, such as the pair of inverters in a static random-access memory (SRAM) cell or the cascaded latch stages of a data flip-flop (DFF) or data latch. Within Table V, the transistors, capacitors, and external lines listed for each instance identify the specific devices and interconnections in the circuit schematic that correspond to the respective first fabric, second fabric, and logic core of that instance.

While various embodiments have been described above, it should be understood that they have been presented only as illustrations and examples of the present disclosure, and not by way of limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments but should be defined only in accordance with the appended claims and their equivalents. It will also be understood that each feature of each embodiment discussed herein, and of each reference cited herein, can be used in combination with the features of any other embodiment.

The present specification provides novel logic structures with several advantages over the prior art. For example, the logic structures can provide compatibility with low-temperature, flexible, or glass-based substrates due to lower fabrication cost using a single type of unipolar thin-film transistor. The structures can provide a reduction in static leakage current compared to conventional diode-configured unipolar TFT logic and memory circuits and avoid of direct current paths between VDD and VSS in static conditions through architectural control of on-and off-state transistors. Certain embodiments can provide the ability to achieve full output voltage swing without complementary transistor types, using bootstrapped feedback structures. Logic functionality can be provided with reduced cost and complexity compared to dual-polarity or resistor-load logic and memory designs. The specification also provides support for scalable integration of logic circuits directly onto TFT backplanes, enabling system-on-panel (SoP) architectures; suitability for use in SRAM, D flip-flops, latches, and other sequential or combinational logic primitives. The teachings can be extended to dynamic and dual-edge triggered configurations without significant increase in static power consumption. Design flexibility is provide by allowing reuse of the same logic core structure with varying external line configurations, including single-ended or differential access schemes.

What is claimed is:

1. A logic structure including unipolar thin-film transistors (uTFTs) of the same type for connection to a plurality of external lines comprising:
a logic-core;
a first-fabric connected to the logic core including:
a first plurality of switching-uTFTs each with an on-state and an off-state;
each of the first plurality of switching-uTFT having:
a first-fabric external terminal connected to one of the external lines;
a first-fabric logic terminal connected to the logic core; and,
a first-fabric gate terminal connected to the logic core for selectively
activating the on-state or the off-state; and,
a second-fabric connected to the logic-core, including:
a second plurality of switching-uTFTs each with an on-state and an off-state; each of the second plurality of switching u-TFT having:
a second-fabric external terminal connected to another one of the external lines;
a second-fabric logic terminal connected to at least one of the first plurality of switching uTFts via the logic core; and,
a second fabric gate terminal connected to a node that is distinct from any of the external lines.

2. The logic structure of claim 1 wherein the uTFTs are all p-type.

3. The logic structure of claim 1 wherein the uTFTs are all n-type.

4. The logic structure of clam 1 wherein logic structure is an SRAM and the logic core connects to a plurality of additional external lines including a word line (WL), and at least one bit line (BL), and wherein the node is distinct from any of the additional external lines.

5. The logic structure of claim 4 wherein:
the first-fabric includes four uTFTs;
the second-fabric comprise four uTFTS;
the logic core comprises at least two additional uTFTs.

6. The logic structure of claim 5, wherein the logic core comprises at least four additional uTFTs including a pair of uTFTs forming an access path to the at least one bit line (BL) and a pair of uTFTs forming a dedicated read port coupled to a read bit line (RBL).

7. The logic structure of claim 6 wherein the logic core further comprises a second pair of uTFTs forming a complementary read port coupled to a second read bit line (RBLB) to provide differential read capability.

8. The logic structure of claim 5, wherein a first one of the second-fabric logic terminals is a drain connected to a node Qb in the logic core and a second one of the second-fabric logic terminals is a drain connected to a node Q in the logic core.

9. The logic structure of claim 4 wherein the plurality of additional external lines includes a second bit line, a read word line and a read bit line.

10. The logic structure of claim 4, wherein the logic core comprises a latch formed by first and second inverters connected in a back-to-back configuration, the first inverter corresponding to the first fabric and the second inverter corresponding to the second fabric.

11. The logic structure of clam 1 wherein the logic core is a data flip-flop.

12. The logic structure of claim 11 wherein the logic core includes a plurality of additional uTFts and capacitors, and wherein a first node is feedback to a gate of a first additional uTFt; and a second node is feedback to a gate of a second additional uTFt;, a third node is feedback to a gate of a third additional uTFt, and an output is feedback to a gate of a fourth additional uTFs.

13. The logic structure of claim 12, wherein the feedback configuration eliminates a short-circuit path between the external lines in a logic “0” output state and a logic “1” output state.

14. The logic structure of claim 11, wherein the logic core employs a bootstrapping technique to achieve full output swing and includes an output feedback from a node in the logic core to a gate terminal of one of the first plurality of switching-uTFTs to form a half-latch configuration that reduces static power consumption by eliminating any direct-current path between VDD and VSS.

15. The logic structure of claim 11, wherein the logic core is implemented in a two-master, one-slave architecture; the logic core being configured such that, during a negative edge of a clock signal, data is loaded into the first master latch, and during a positive edge of the clock signal, data is loaded into the second master latch, the slave latch being configured to selectively receive data from the first master latch during the positive edge and from the second master latch during the negative edge, wherein full output swing is achieved using bootstrapped logic.

16. The logic structure of claim 11 wherein a plurality of the data flip-flops are connected in series to form a scan-chain of data flip-flops.

17. The logic structure of clam 1 wherein the logic core is a data latch.

18. The logic structure of claim 1, wherein the logic core is a data latch configured to receive an input, a clock signal, and a complementary clock signal, the logic core including a capacitor and being arranged to employ a bootstrap technique to achieve full output swing, with an output feedback from an output node and from an internal node to form a half-latch configuration.
